(19) United States
(12) Patent Application Publication
(10) Pub. No.: US 2026/0101464 A1
(43) Pub. Date: Apr. 9, 2026

(54) SERVER CLUSTER CONTAINER AND CONTAINERIZED SERVER CLUSTER APPARATUS

(71) Applicant: Canaan Creative Co., Ltd., Beijing (CN)

(72) Inventors: Guanchao Zhao, Beijing (CN); Nan Li, Beijing (CN); Shishuang He, Beijing (CN); Zonghai Chen, Beijing (CN); Xiaogang Sun, Beijing (CN); Xiaoye Zhao, Beijing (CN); He Ying, Beijing (CN); Nangeng Zhang, Beijing (CN)

(21) Appl. No.: 19/479,404

(22) PCT Filed: Mar. 7, 2024
(86) PCT No.: PCT/CN2024/080554

§ 371 Date: Oct. 28, 2025

(30) Foreign Application Priority Data
Apr. 28, 2023 (CN) 20321029522.5
May 17, 2023 (CN) 20231197059.5

(51) Int. Cl. H05K 7/14; H05K 7/20

(52) U.S. Cl. CPC H05K 7/1492; H05K 7/1491; H05K 7/20736

(57) ABSTRACT

Disclosed in the present application are a server cluster container and a containerized server cluster apparatus. The server cluster container in the present application comprises a container body, and a rack and an electronic control system, which are arranged in the container body, wherein the electronic control system comprises a power distribution cabinet, which is connected to servers borne on the rack. The containerized server cluster apparatus comprises the server cluster container and a plurality of servers, wherein the servers are arranged on the rack and are connected to the electronic control system. In the present application, the plurality of servers are containerized in the server cluster container to form the containerized server cluster apparatus, which has high-density deployment, high computational efficiency and high mobility.

### CROSS-REFERENCE TO RELATED APPLICATIONS

The present application claims priority to Chinese Patent Application No. 202321029522.5 filed on Apr. 28, 2023, and priority to Chinese Patent Application No. 202321197059.5 filed on May 17, 2023, and these patent applications are incorporated herein by reference for all purposes as if fully set forth herein.

### TECHNICAL FIELD

The present application relates to the field of computing devices, and specifically to a server cluster container and a containerized server cluster apparatus.

### BACKGROUND

Container server clusters are a cluster apparatus that integrates a plurality of servers, cooling systems, power supplies, control systems and other components in a single container. With the rapid growth in data processing demands, the container server clusters have gained significant attention due to their features such as ease of transportation and deployment.

How to configure a containerized server cluster in a container and improve the working efficiency of the server cluster is a technical problem that needs to be solved by those skilled in the art.

### SUMMARY

An objective of the present application is to provide a server cluster container, which improves the working efficiency of a server cluster through a reasonable layout in the container.

Another objective of the present application is to provide a containerized server cluster apparatus including the above server cluster container.

In order to achieve the above objectives, the server cluster container of the present application includes a container body, and a rack and an electronic control system which are respectively disposed in the container body, the electronic control system including a power distribution cabinet connected with servers borne on the rack. In the present application, the plurality of servers are containerized in the server cluster container to form the containerized server cluster apparatus, which has high-density deployment, high computational efficiency and high mobility.

Regarding the above server cluster container, the rack and the power distribution cabinet are disposed in a row along a length direction of the container body to form an apparatus row, integrating a larger number of servers in an optimal spatial arrangement and making full use of a space in the container body.

Regarding the above server cluster container, the racks are configured on two sides of the power distribution cabinet. In the present application, by disposing the racks on the two sides of the power distribution cabinet, power lines leading out of two ends of the power distribution cabinet supply power to servers on the racks on the two sides, and the power lines leading out of the two ends of the power distribution cabinet are clearly routed, which makes it easy for staff to manage and maintain and can avoid troubles caused by too many and too long power lines and complex wiring redundancy due to single-side cabling, thereby reducing maintenance manpower and apparatus costs.

Regarding the above server cluster container, the container body includes a first side heat dissipation long edge extending along the length direction, the first side heat dissipation long edge being provided with a dustproof mesh and/or a shutter structure and/or a water curtain structure. By providing the dustproof mesh and/or shutter structure and/or water curtain structure, heat dissipation is performed for the servers in the container body, ensuring high-efficiency operation of the system.

Regarding the above server cluster container, the container body includes a second side heat dissipation long edge extending along the length direction, a position on the second side heat dissipation long edge corresponding to the power distribution cabinet being provided with a maintenance door. By providing the maintenance door that is located outside a second long side edge of the container body and faces the power distribution cabinet, when maintenance is required, the staff arrive at outside of the second long side edge, open the maintenance door, and then may directly walk into the container body to conduct professional operations on the power distribution cabinet.

Regarding the above server cluster container, the second side heat dissipation long edge is provided with a cooling structure. By providing the cooling structure, heat dissipation is performed for the servers in the container body, ensuring high-efficiency operation of the system.

The first side heat dissipation long edge and the second side heat dissipation long edge are disposed oppositely to form convection air cooling, resulting in good cooling effect and low cost.

Regarding the server cluster container, a first maintenance passage is present between the first side heat dissipation long edge and the apparatus row of the container body. The first maintenance passage of the present application is spacious and smooth, which is used for the staff to conduct regular inspection, maintenance and upkeep for systems, apparatuses, networks, and the like to ensure that they can normally operate, prevent failures and accidents, and improve the reliability and stability of the systems.

Regarding the above server cluster container, the container body includes a first side short edge and a second side short edge which extend symmetrically along a width direction, a position of the first side short edge and/or the second side short edge corresponding to the first maintenance passage being provided with a door. By providing the door on at least one side of the first side short edge and the second side short edge corresponding to the first maintenance passage, the staff may enter the maintenance passage from the door, to inspect, maintain and service the systems, apparatuses and networks in the container body, and then walk out from the door, which is convenient and quick and can effectively improve the working efficiency.

Regarding the above server cluster container, a floor in the container body corresponding to the first maintenance passage is an insulating panel. The insulated floor can effectively isolate electrical connections between the ground and electrical apparatuses, protecting the safety of personnel and apparatuses.

Regarding the above server cluster container, positions of the first side short edge and/or the second side short edge of the container body corresponding to the rack and positions between the rack and the second side heat dissipation long edge of the container body are provided with closed walls. Where the first side short edge and the second side short edge do not correspond to the first maintenance passage, there are the closed walls sealed to top, which simplifies unnecessary design, and reduces safety hazards and the costs of maintenance and apparatus manufacturing.

Regarding the server cluster container, a second maintenance passage is present between the second side heat dissipation long edge and the apparatus row of the container body. The second maintenance passage is a passage that may be used for maintaining the cooling structure on the second side heat dissipation long edge and the apparatuses in the apparatus row.

Regarding the above server cluster container, a width of the second maintenance passage along the width direction of the container body is greater than a thickness of the cooling structure, so that the cooling structure can be built into the container body.

Regarding the above server cluster container, a floor in the container body corresponding to the second maintenance passage is a steel plate, which can provide a robust ground support and increase the strength and stability of the container body.

Regarding the above server cluster container, a position on the first side heat dissipation long edge of the container body corresponding to the power distribution cabinet is provided with a wall panel, a top of the wall panel having a cable inlet corresponding to a top end of the power distribution cabinet. The cable inlet directly corresponds to a top of the power distribution cabinet, and power cables are introduced through the cable inlet and connected to the power distribution cabinet, resulting in a direct path, shortening the length of the power cables inside and outside the container body, reducing the space occupied by the power cables in the container body, avoiding the accumulation and extension of a large number of large-volume power cables in the container body, and facilitating the staff's daily inspection, maintenance and upkeep work on the systems, apparatuses and networks in the container body.

Regarding the above server cluster container, a cable support structure is disposed between the top of the power distribution cabinet and the cable inlet for bearing power cables introduced through the cable inlet and connected to the power distribution cabinet.

Regarding the above server cluster container, the cable support structure includes a cable tray for supporting the power cables and a hoisting structure for hoisting the cable tray to the top of the container body.

Regarding the above server cluster container, the container body includes a bottom plate, the rack extending vertically and being fixed on the bottom plate, and the power distribution cabinet being fixed on the bottom plate. The apparatus row consisting of the power distribution cabinet and the rack is fixedly connected with the bottom plate of the container body, avoiding tipping and shifting during loading, unloading and transportation.

Regarding the above server cluster container, the rack and the power distribution cabinet are fixed to each other. The rack and the power distribution cabinet are fixed to each other using connectors, making the structure firmer. In a process of long-distance transportation of the container, due to the influence of roads, weather, human factors, etc., the container may be subject to impact, tilting, or shaking, resulting in damage to goods. The server cluster container of the present application provides stable fixation of the rack and the power distribution cabinet inside the container body, making long-distance transportation more stable and safer.

Regarding the above server cluster container, the rack includes a plurality of partition plates that are in a mesh structure. The mesh-shaped partition plates will not block servers placed thereon, which facilitates the staff's timely observation of a situation of each indicator light of each server, as well as constant awareness of a working status of the server, so that it can be quickly found whether the server has failures or abnormal conditions, helping to take timely measures to prevent the server from shutting down due to failures and improve the reliability and stability of the server.

Regarding the above server cluster container, the rack includes a cable management slot including L-shaped clips that are disposed oppositely. The cable management slot is used for routing and storing communication cables and other cables. The cable management slots are, for example, disposed at intervals along the partition plate to neatly fix the cables in the cable management slots. The cable management slots can avoid cables being loose, dropped and entangled, reducing wire damage and thereby improving the apparatus safety and production efficiency, which can also make the container body tidier to provide convenience for the staff's daily maintenance and management.

Regarding the above server cluster container, the electronic control system includes a plurality of power distributors connected to the power distribution cabinet, the power distributors being configured on outer sides of the partition plates for providing power sources for the servers disposed on the partition plates of the rack.

Regarding the above server cluster container, the power distributors are configured on the partition plates that are not at a bottommost layer. That is, no power distributors are configured on a bottommost-layer partition plate of the rack, avoiding damage to the power distributors from moisture and stains.

Regarding the above server cluster container, the rack further includes an extension baffle extending horizontally out from the partition plate, which increase a length of the rack along the width direction.

Regarding the above server cluster container, outer sides of the partition plate and/or the extension baffle are provided with the power distributors, which provide power sources for the servers disposed on the partition plate and/or extension baffle of the rack.

Regarding the above server cluster container, the partition plates include high partition plates higher than or equal to a set height and low partition plates lower than the set height, and the extension baffle is disposed on an outer side of each of the high partition plates. This set height is, for example, a height of maintenance personnel. That is, the extension baffle is disposed at a position higher than the height of the maintenance personnel, thereby expanding the support space of the rack without affecting the daily work of the maintenance personnel.

Regarding the above server cluster container, the extension baffle is disposed on an outer side of a topmost-layer partition plate, which increases the number of integrated servers based on the limited space and can improve the computing power of the containerized server cluster apparatus.

Regarding the above server cluster container, it further includes a top-layer apparatus status feedback means. During maintenance, the staff can be timely aware of a working status of a server located at the topmost layer.

Regarding the above server cluster container, the top-layer apparatus status feedback means includes a reflective mirror observation means. The top-layer apparatus status feedback means employs the reflective mirror observation means, which can achieve real-time monitoring of the server status by means of a status indicator light of the server itself without investing any software or hardware in the server. There may be one or more reflective mirror observation means.

Regarding the above server cluster container, the reflective mirror observation means includes a plurality of feedback areas, each corresponding to at least one server disposed on the topmost-layer partition plate and/or the extension baffle, and feeding back a working status of each server in real time, which facilitates timely processing by the staff and ensures the working efficiency of the apparatus.

Regarding the above server cluster container, it further includes an intelligent monitoring system connected to the electronic control system. The intelligent monitoring system can improve the reliability, stability, and safety of the apparatus, reduce the maintenance costs and improve the working efficiency, and can also provide data support to help the management and optimization of the apparatus.

Regarding the above server cluster container, the intelligent monitoring system further includes one of an access control module, a lighting sensor module, an anti-theft monitoring module and a fire prevention module, which performs intelligent monitoring on each functional module of the entire system and handles abnormal conditions in a timely manner.

Regarding the above server cluster container, a side of the rack along the length direction of the container body is provided with an isolation plate. A plane where the isolation plate is located divides the inside of the container into two zones: a hot zone and a cool zone, of which the cool zone is where the first maintenance passage is located, and the hot zone is the other zone.

Regarding the above server cluster container, the isolation plate is disposed close to air outlets of the servers borne on the rack. The plurality of servers mounted and configured on the rack have air inlets and air outlets, the air inlets of the servers being located in the cold zone and the air outlets of the servers being located in the hot zone.

Regarding the above server cluster container, the isolation plate is provided with vents corresponding to the air outlets of the servers borne on the rack. The isolation plate is provided with the vents corresponding to the air outlets of the servers, so that hot air in the servers is discharged to the cold zone, and so that the isolation plate not only ensures smooth discharge of the hot air from the servers, but also can avoid hot air in the hot zone from flowing back to the cold zone.

The containerized server cluster apparatus of the present application includes a plurality of servers, which further includes the above server cluster container, the servers being arranged and disposed on the rack and connected to the electronic control system.

The following detailed description of the present application will be made in conjunction with the drawings and specific embodiments, but is not intended to limit the present application.

### BRIEF DESCRIPTION OF THE DRAWINGS

FIG. 1 is a perspective structural diagram of an embodiment of a server cluster container of the present application;

FIG. 2 is a perspective structural diagram of an embodiment of a server cluster container of the present application (with the first side heat dissipation long edge not shown);

FIG. 3 is a front view of an embodiment of a server cluster container of the present application (viewed from the first side heat dissipation long edge);

FIG. 4 is a front view of an embodiment of the present application where a container power distribution bracket arrangement is shown;

FIG. 5 is a perspective structural diagram of an embodiment of a server cluster container of the present application (with the container body top plate not shown);

FIG. 6 is a perspective structural diagram of an embodiment of a server cluster container of the present application (with the container body top plate not shown);

FIG. 7 is a top view of an embodiment of a server cluster container of the present application (with the container body top plate not shown);

FIG. 8 is a side view of an embodiment of a server cluster container of the present application;

FIG. 9 is a front view of an embodiment of a server cluster container of the present application (viewed from the first side heat dissipation long edge);

FIG. 10 is a partial view of a cable tray and baffle rods of a server cluster container of the present application;

FIG. 11 is a front view of an embodiment of a server cluster container of the present application (viewed from the second side heat dissipation long edge);

FIG. 12 is a perspective structural diagram of an embodiment of a rack of a server cluster container of the present application;

FIG. 13 is a partial enlarged view of FIG. 12; and

FIG. 14 is a side view of an embodiment of a rack of a server cluster container of the present application (connected to power distributors).

### REFERENCE NUMERALS

1: Server cluster container
11: Corner post
12: Bottom side beam
13: Top side beam
14: Corner member
100: Container body
110: First side heat dissipation long edge
120: Second side heat dissipation long edge
130: First side short edge
140: Second side short edge
150: Bottom plate
200, 200a, 200b, 200c, 200d: Rack
210, 210a, 210b, 210c, 210d, 210e, 210f, 210g: Partition plate
230: Extension baffle
240: Cable management slot
310, 310a, 310b: Power distribution cabinet
330a1, 330a2, 330b, 330c, 330d, 330e, 330f: Power distributor
400: Apparatus row
500: First maintenance passage
600: Door
700: Closed wall
801: Wall panel
802: Cable inlet
803: Cable tray
804: Baffle rod
900: Maintenance door
S: Container power distribution bracket arrangement

### DETAILED DESCRIPTION

The following describes the technical solutions of the present application in detail in conjunction with the drawings and specific embodiments so as to further understand the objectives, solutions and effects of the present application, but not to limit the scope of protection of the appended claims of the present application.

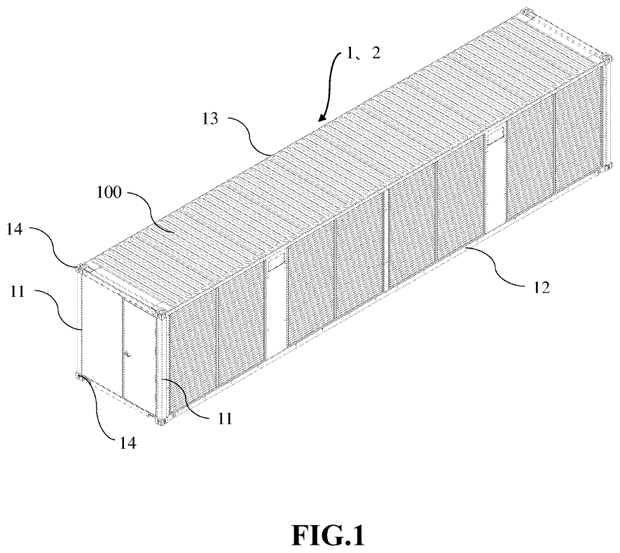

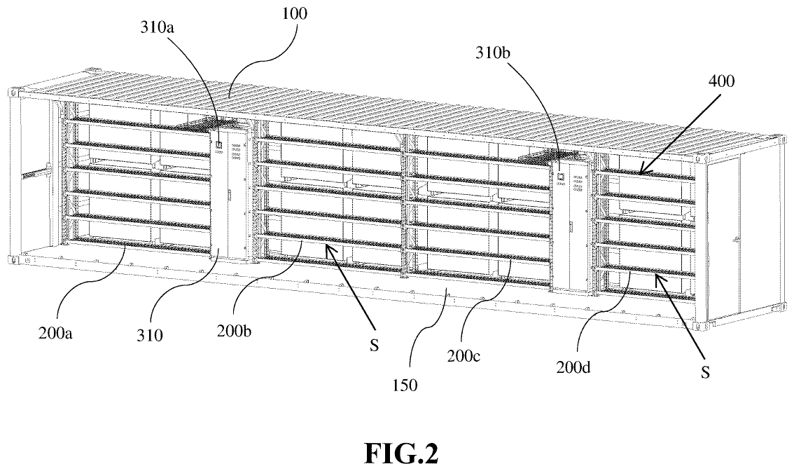

Currently, containerized servers have become a mainstream apparatus in the computing device industry. A server cluster container 1 in some embodiments of the present application is used for loading and integrating a plurality of server apparatuses to form a containerized server cluster apparatus. With reference to FIGS. 1 and 2, the server cluster container 1 in some embodiments of the present application includes a container body 100, a rack 200 and an electronic control system, the rack 200 and the electronic control system being respectively disposed and integrated in the container body 100, wherein the rack 200 is used for bearing a plurality of servers, and the electronic control system connects the plurality of servers borne on the rack 200 to provide services such as power distribution and communication for the servers.

The electronic control system includes a power distribution cabinet 310 connected with the servers borne on the rack 200. The power distribution cabinet 310 is used, for example, to supply power for the entire system, and includes at least one of the following components: a main power input, a power management unit, a battery pack, and a UPS (uninterruptible power supply).

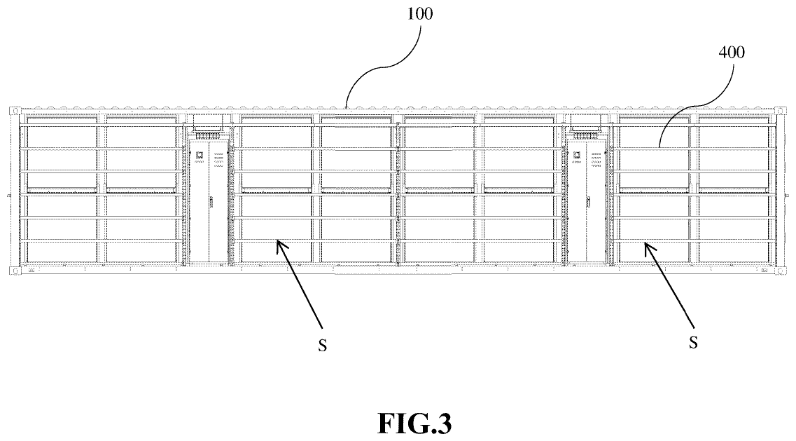

As shown in FIGS. 2 and 3, the racks 200 and the power distribution cabinet 310 are disposed in a row along a length direction of the container body 100 to form an apparatus row 400, making full use of a space inside the container body 100.

In some embodiments, the racks 200 are configured to be disposed on two sides of the power distribution cabinet 310.

By disposing the racks 200 on the two sides of the power distribution cabinet 310, power lines leading out of two ends of the power distribution cabinet 310 supply power to servers on the racks 200 on the two sides, and the power lines leading out of the two ends of the power distribution cabinet 310 are clearly routed, which makes it easy for staff to manage and maintain.

In some embodiments, the racks 200 are configured to be symmetrically disposed on the two sides of the power distribution cabinet 310.

By providing a symmetrical configuration of the racks 200 on the two sides of the power distribution cabinet 310, the same number of servers of the same specifications can be arranged on the racks 200, so that power lines leading out of the two ends of the power distribution cabinet 310 are evenly distributed and clearly routed, which makes it easy for the staff to manage and maintain and can avoid troubles caused by too many and too long power lines and complex wiring redundancy due to single-side cabling, thereby reducing maintenance manpower and apparatus costs. Moreover, this can further ensure the overall counterweight balance of the container and increase the overall reliability of the apparatus.

In some embodiments, one rack 200a and one rack 200b, as shown, are respectively configured on two sides of the power distribution cabinet 310a. The racks 200a and 200b have the same specifications, or in other words, the racks 200a and 200b have the same length, same width, and same height so as to have the ability to bear the same number of servers of the same specifications.

It should be noted that the “one” rack here does not refer to one in the physical sense, but means that the racks on the two sides of the power distribution cabinet have the same specifications and have the same ability to bear servers, so that the power distribution cabinet evenly supplies power to the two sides. The racks on the two sides of the power distribution cabinet may also be connected to each other to form an integrated whole.

In other embodiments, the two sides of the power distribution cabinet 310 may be symmetrically configured with two or more racks 200 of the same number and specifications, so as to ensure that the power distribution cabinet 310 evenly routes and transmits power to servers on the racks in directions of the two sides.

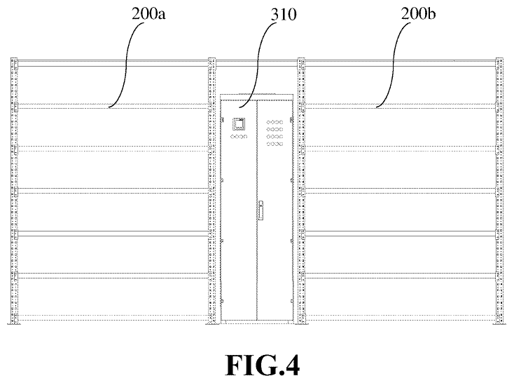

As shown in FIG. 4, one power distribution cabinet 310 along with racks 200 symmetrically disposed on its two sides serves as a container power distribution bracket arrangement S. Of course, the container power distribution bracket arrangement S may also include matching accessories such as power lines, communication lines. In the embodiments shown in FIGS. 2 and 3, two container power distribution bracket arrangements S are disposed in the container body 100. That is, two sides of a power distribution cabinet 310a are respectively configured with the racks 200a and 200b of the same specifications, and two sides of a power distribution cabinet 310b are respectively configured with racks 200c and 200d of the same specifications. Preferably, the racks 200a, 200b, 200c, and 200d have the same specifications, so that balance can be achieved in both power line distribution and weight distribution.

The two container power distribution bracket arrangements S are provided and arranged side by side in a row. On the premise of ensuring the reliability of electrical control measures such as power distribution, the number of configurable servers is multiplied, and the computing power of the containerized server cluster apparatus is multiplied. When the computing power of the containerized server cluster apparatus is increased, requests and tasks can be processed faster, thereby improving response speed and processing efficiency, supporting the processing of large amounts of data and more complex applications, and meeting higher performance requirements.

Of course, in other embodiments, depending on a size of the container body 100, computing power requirements and a power distribution mode, only one container power distribution bracket arrangement S may be disposed in the container body 100, or three or even more container power distribution bracket arrangements S may be disposed.

The above electronic control system not only has power distribution function, but also includes air conditioning function, cabinet power management function, remote monitoring function and the like, which ensure the normal operation and management of the server container through collaboration among various components. The air conditioning function part includes an air conditioning controller, a compressor, a fan and other components, which are used for maintaining a temperature and humidity inside the server container. The cabinet power management function part is used for monitoring and managing a power supply of each cabinet, including powering on and off, restarting, monitoring power consumption, etc. The remote monitoring function part is used for remotely monitoring a status of the server container, including collecting and analyzing information such as temperature, humidity, power consumption, and network connection.

Referring back to FIG. 1, the set container 1 in some embodiments of the present application employs the structural form of a standard container. For example, the container body 100 of the set container 1 in some embodiments of the present application is made of materials such as steel, aluminum alloy, etc., and has the characteristics of high strength, corrosion resistance, and wear resistance. The container body 100 has a corner post 11, a bottom side beam 12, a top side beam 13, a corner member 14, etc. like those configured in the standard container, which are main structural components of the container and are used for supporting and reinforcing the container body 100 to make the same strong and rigid enough to withstand the weight of goods and the vibrations and impacts experienced in a transportation process.

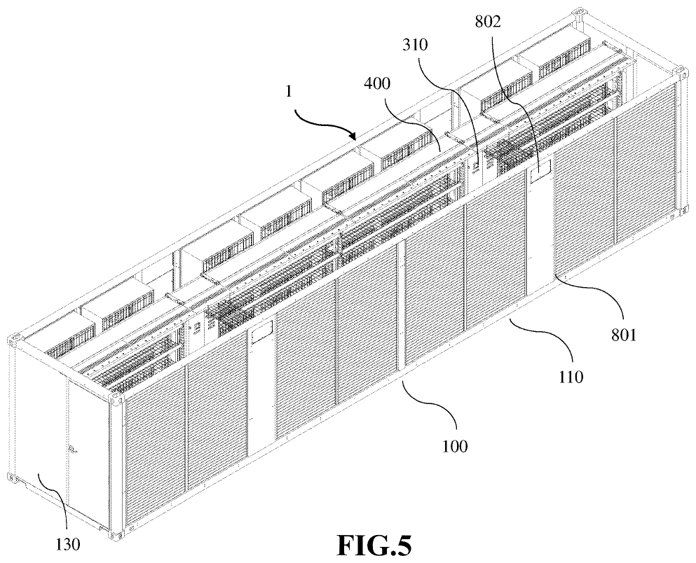

As shown in FIGS. 5 to 7, the container body 100 of the server cluster container 1 in some embodiments of the present application includes a first side heat dissipation long edge 110, a second side heat dissipation long edge 120, a first side short edge 130, and a second side short edge 140, wherein the first side heat dissipation long edge 110 and the second side heat dissipation long edge 120 are symmetrically disposed along the length direction of the container body 100, and the first side short edge 130 and the second side short edge 140 are symmetrically disposed along the width direction of the container body 100.

In some embodiments of the present application, the first side heat dissipation long edge 110 and the second side heat dissipation long edge 120 are provided with an air inlet and an air outlet, and a heat dissipation channel is formed between the air inlet and the air outlet. In some embodiments of the present application, the first side heat dissipation long edge 110 and/or the second side heat dissipation long edge 120 are provided with a cooling structure. In some embodiments of the present application, the first side heat dissipation long edge 110 and/or the second side heat dissipation long edge 120 are provided with a dustproof mesh and/or shutters. In some embodiments of the present application, the first side heat dissipation long edge 110 is provided with a water curtain structure, and the second side heat dissipation long edge 120 are provided with a fan cooling structure.

The server cluster container 1 in some embodiments of the present application is a hexahedral shape formed by extending the first side heat dissipation long edge 110, the second side heat dissipation long edge 120, the first side short edge 130 and the second side short edge 140 to a height, a size of which may be the same as a current mainstream standard container size, such as 20-foot, 40-foot, etc. During loading, unloading and transportation, the same loading, unloading and transportation forms as those of standard containers may be employed. For example, the same loading and unloading equipment as that for standard containers, such as hoisting and forklifts, as well as the same transportation equipment such as land transportation vehicles and sea transportation ships may be used, which greatly reduces transportation costs. Of course, the server cluster container 1 in some embodiments of the present application may also be smaller than a standard container, which, when transported, is loaded in the standard container to avoid damage such as collision and displacement that may occur in transportation, loading and unloading processes. Further, one standard container may be loaded with one or more of the server cluster containers 1 in some embodiments of the present application.

The apparatus row 400 formed by disposing the rack 200 and the power distribution cabinet 310 in a row is disposed along a direction in which the first side heat dissipation long edge 110 and the second side heat dissipation long edge 120 extend, and two sides of the apparatus row 400 respectively abut against the first side short edge 130 and the second side short edge 140.

The containerized server cluster apparatus is a high-power density apparatus that consumes a great amount of electrical energy to work, and accordingly generates a great amount of heat in a working process, which requires heat dissipation treatment to ensure the normal operation of the apparatus.

The server cluster container 1 in some embodiments of the present application employs air cooling for heat dissipation which is a high-efficiency and low-consumption heat dissipation manner involving a principle of introducing external air into the inside of the container, transferring heat to the air, and then discharging the hot air to the outside of the container to reach the purpose of heat dissipation.

The first side heat dissipation long edge 110 is provided with an air inlet structure, and the second side heat dissipation long edge 120 is provided with a cooling structure. The first side heat dissipation long edge 110 and the second side heat dissipation long edge 120 as disposed oppositely form an air flow to dissipate heat from and cool the servers in the container body 100.

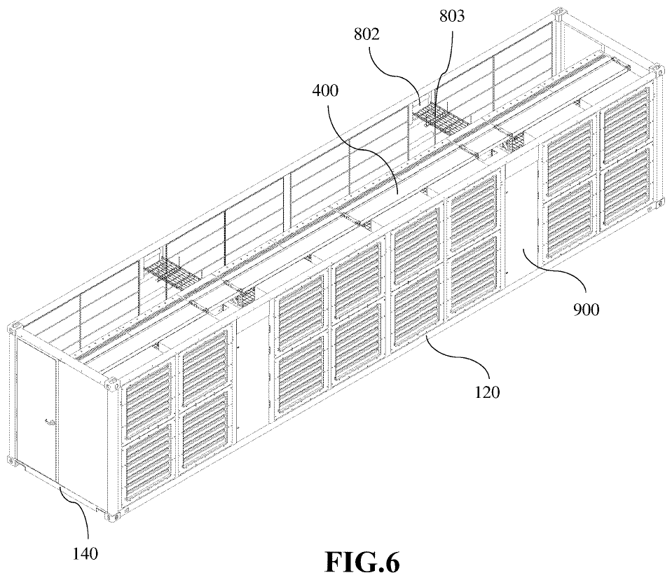

In an embodiment, a shutter structure is provided on the first side heat dissipation long edge 110, and a cooling fan is provided on the second side heat dissipation long edge 120 (as shown in FIG. 6). Alternatively, a dustproof mesh structure is provided on the first side heat dissipation long edge 110, and the cooling fan is provided on the second side heat dissipation long edge 120 (not shown), wherein the dustproof mesh structure is, for example, a metal cut mesh or a metal woven mesh with mesh holes. Alternatively, shutter and dustproof mesh structures are provided on the first side heat dissipation long edge 110, and the cooling fan is provided on the second side heat dissipation long edge 120, both having good impurity prevention and wind cooling effects. Alternatively, a water curtain structure is mounted on the outer side of the first side heat dissipation long edge 110, so that air outside the container body 100 enters into the cavity through a wet curtain with strong water absorption, water on the wet curtain evaporates under an adiabatic state to remove a large amount of latent heat, the purified, cooled and oxygenated cold air is sent into the container body 100, and through continuous convection, the heat dissipation effect is further improved. Alternatively, at least two of the dustproof mesh structure, the shutter structure, and the water curtain structure are mounted on the outer side and/or inner side of the first side heat dissipation long edge 110.

It should be noted that the second side heat dissipation long edge 120 is provided with a plurality of cooling fans. By introducing external air into the inside of the container and allowing the air to flow through the cooling fans, the heat will be removed, so as to keep a temperature inside the container from being too high. In other embodiments, the cooling fans may be used in combination with heat dissipation pipes consisting usually of a series of metal pipes, through which heat is transferred to container walls and then dissipated to the external air. This manner can increase the heat dissipation area of the container and improve the heat dissipation effect. Alternatively, the cooling fans may be used in combination with heat dissipation fins consisting usually of a series of metal sheets, through which heat is transferred to the air and then removed. This manner can increase the heat dissipation area of the container and improve the heat dissipation effect. In order to ensure the heat dissipation effect, it is necessary to ensure smooth air circulation around the container.

In some embodiments of the present application, the first side heat dissipation long edge 110 and the second side heat dissipation long edge 120 are disposed oppositely, making the structure simple, the costs low, and the heat dissipation effect good.

Further, a water curtain structure is mounted on the outer side of the first side heat dissipation long edge 110, so that air outside the container body 100 enters into the cavity through a wet curtain with strong water absorption, water on the wet curtain evaporates under an adiabatic state to remove a large amount of latent heat, the purified, cooled and oxygenated cold air is sent into the container body 100, and through continuous convection, the heat dissipation effect is further improved.

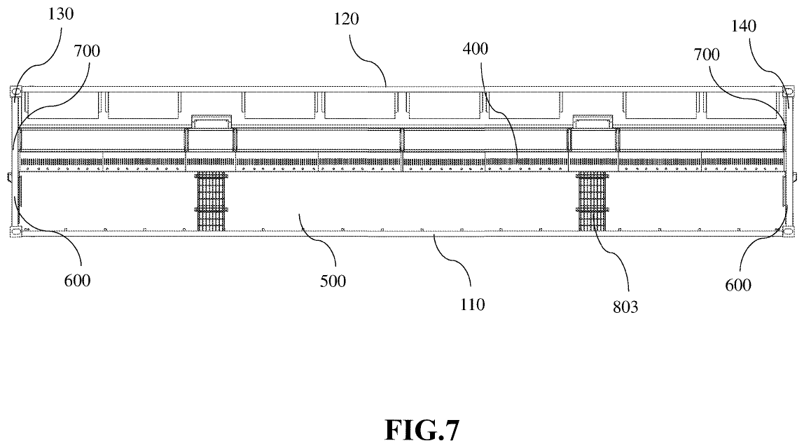

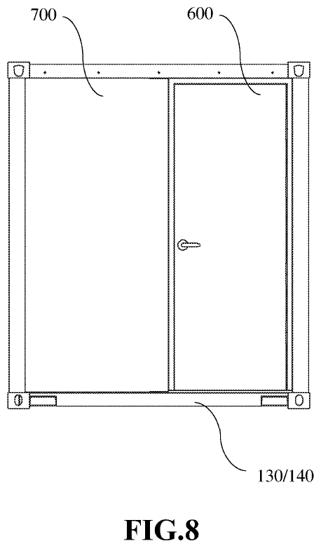

As shown in FIGS. 7 and 8, a first maintenance passage 500 is provided between the first side heat dissipation long edge 110 and the apparatus row 400, and doors 600 are provided at positions of the first side short edge 130 and the second side short edge 140 corresponding to the first maintenance passage 500.

The apparatus row 400 is disposed in parallel between the first side heat dissipation long edge 110 and the second side heat dissipation long edge 120, and the first maintenance passage 500 between the first side heat dissipation long edge 110 and the apparatus row 400 is used for the staff to conduct regular inspection, maintenance and upkeep for systems, apparatuses, networks, and the like to ensure that they can normally operate, prevent failures and accidents, and improve the reliability and stability of the systems. The regular maintenance and upkeep can extend the service life of the systems, apparatuses, networks, and the like, reduce the frequency and cost of replacement and repair, and optimize the systems, apparatuses, networks, and the like, thereby improving system performance and efficiency and reducing resource wastes. Meanwhile, the maintenance passage can also be used to perform security inspection and protection on the systems, apparatuses, networks, and the like to ensure the security and confidentiality of information. As can be seen, the maintenance passage plays an important role in ensuring the normal operation of the systems and improving the reliability, stability, performance and security of the systems.

The first maintenance passage 500 in some embodiments of the present application is spacious and smooth, and at least one side of the first side short edge 130 and the second side short edge 140 corresponding to the first maintenance passage 500 is provided with a door 600. In this embodiment, doors 600 are respectively disposed on the first side short edge 130 and the second side short edge 140, and the staff may enter the first maintenance passage 500 from one of the doors 600, to inspect, maintain and service the systems, apparatuses and networks in the container body 100, and then walk out from the other door 600, which is convenient and quick and can effectively improve the working efficiency.

A floor of the first maintenance passage 500 in the embodiments of the present application employs an insulating material, ensuring the electrical safety for the staff when they are performing apparatus maintenance and repair.

In the embodiments of the present application, the door 600 employs an escape door structure, ensuring that the staff can smoothly open the door 600 to escape in dangerous situations.

In an embodiment of the server cluster container 1 in some embodiments of the present application, positions of the first side short edge 130 and the second side short edge 140 corresponding to the rack 200 and between the rack 200 and the second side heat dissipation long edge 120 are closed walls 700. That is to say, the doors 600 disposed on the first side short edge 130 and the second side short edge 140 are half-open doors, and only the positions thereof corresponding to the first maintenance passage 500 are openable/closeable doors, while where the first side short edge 130 and the second side short edge 140 do not correspond to the first maintenance passage 500, there are closed walls sealed to top, which simplifies unnecessary design, and reduces safety hazards and the costs of maintenance and apparatus manufacturing.

Meanwhile, a door lock is disposed on the door 600, which supports a plurality of door opening manners, such as password, fingerprint, card swiping, etc. A suitable unlocking manner may be selected according to an actual case. The door lock also supports a plurality of alarm manners, such as sound alarm, SMS alarm, etc., and alarms are issued for cases where unlocking settings are not met, so as to avoid losses.

In addition, permission management of the door lock may be performed by setting an administrator password to ensure that only the authorized know the password. Further, the door lock permissions are set for different users, such as administrators, maintenance personnel, ordinary users, and the like. Different users have different permissions, which can achieve better management of the door lock. For example, parameters of the door lock such as door opening time, door closing time, and alarm time may be set, so as to meet different usage needs. For example, the door opening time for the ordinary users is limited to a shorter time, the door opening time for the maintenance personnel is a longer time, and the door opening time for the administrators is unlimited, etc.

In some embodiments, a second maintenance passage is provided between the second side heat dissipation long edge 120 and the apparatus row 400. A width of the second maintenance passage along the width direction of the container body 100 is greater than a thickness of the cooling structure. A floor in the container body 100 corresponding to the second maintenance passage is a steel plate, which can provide a robust ground support and increase the strength and stability of the container body.

In some embodiments, a side of the rack along the length direction of the container body is provided with an isolation plate. Exemplarily, the rack and the power distribution cabinet form an apparatus row along the length direction of the container body. A side of the apparatus row along the length direction of the container body is provided with an isolation plate. Exemplarily, the isolation plate is disposed close to air outlets of the servers borne on the rack. Exemplarily, the isolation plate is provided with vents corresponding to the air outlets of the servers borne on the rack.

In some embodiments, a side of the apparatus row 400 consisting of the power distribution cabinet 310 and the rack 200 away from the first maintenance passage 500 is provided with an isolation plate that extends along the length direction and width direction of the container. A height of the isolation plate is substantially consistent with a height of the space inside the container body, and a length of the isolation plate is substantially consistent with a length of the space inside the container body. A plane where the isolation plate is located divides the inside of the container into two zones: a hot zone and a cool zone. The cool zone is a zone where the first maintenance passage 500 is located, while the hot zone is the other zone.

In some embodiments, a plurality of servers are mounted and configured on the rack 200, which have air inlets and air outlets, the air inlets of the servers being located in the cold zone and the air outlets of the servers being located in the hot zone. Correspondingly, the isolation plate is provided with vents corresponding to the air outlets of the servers, so that hot air in the servers is discharged to the cold zone, and so that the isolation plate not only ensures smooth discharge of the hot air from the servers, but also can avoid hot air in the hot zone from flowing back to the cold zone.

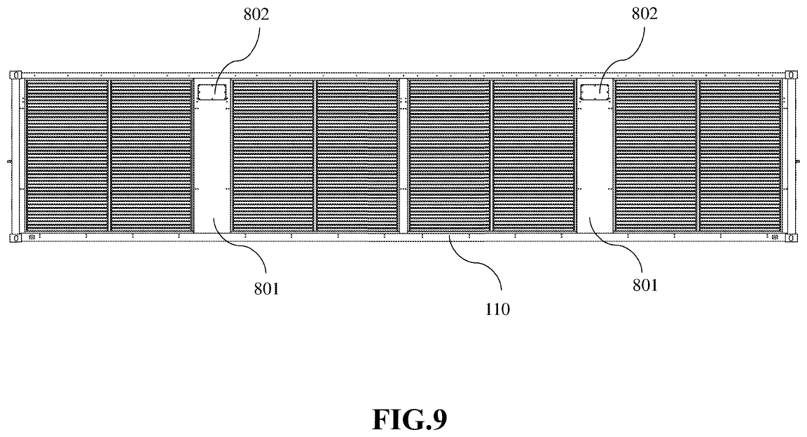

In the server cluster container 1 in some embodiments of the present application, as shown in FIGS. 5, 7, and 9, the apparatus row 400 consisting of the power distribution cabinet 310 and the rack 200 is located between the first side heat dissipation long edge 110 provided with shutters (and/or a dustproof mesh and/or a water curtain structure) and the second side heat dissipation long edge 120, wherein part of the first side heat dissipation long edge 110 corresponding to the power distribution cabinet 310 of the apparatus row 400 is further provided with a wall panel 801, and the shutters (and/or the dustproof mesh and/or the water curtain structure) are disposed corresponding to the position of the rack 200, ensuring that external wind enters the container body 100 through the shutters (and/or the dustproof mesh and/or the water curtain structure), while avoiding moisture or sunlight from damaging the power distribution cabinet 310. As shown in FIG. 9, the wall panel 801 is disposed between adjacent shutters (and/or dustproof meshes and/or water curtain structures).

The wall panel 801 is made of, for example, a steel plate. Part of the wall panel 801 may be added with transverse and longitudinal reinforcing ribs to improve the overall strength of the container body 100, enhance the resistance of the container body 100 to deformation and extrusion, and reduce the possibility of damage during loading, unloading and transportation.

Further, as shown in FIGS. 5 and 6, a top of the wall panel 801 has a cable inlet 802 disposed corresponding to a top end of the power distribution cabinet 310.

Server power cables require the use of high-quality copper-core cables, so as to ensure the stability and reliability of current transmission. Meanwhile, sheaths of the cables should have certain properties, such as wear resistance, high temperature resistance, and corrosion resistance. The length of the server power cables needs to be selected according to actual cases. In general, the cable length should not be too long, so as to avoid excessive resistance and power loss in a current transmission process. The server power cables need to have certain safety properties, such as fireproof, explosion-proof, and electric shock-proof properties. At the time of selecting cables, it should be noted whether they comply with relevant safety certification standards, such as UL, CE, and the like.

A server consumes a lot of electricity, and the cross-sectional area of the server power cables needs to be large enough to meet the high power requirements of the server. When the power distribution cabinet 310 needs to power a large number of servers, both the number and volume of power cables connected with the power distribution cabinet 310 are relatively large.

In some embodiments of the present application, by disposing at a top end of the wall panel 801 the cable inlet 802 that directly corresponds to the top of the power distribution cabinet 310, the power cables are introduced through the cable inlet 802 and connected to the power distribution cabinet 310, resulting in a direct path, shortening a length of the power cables inside and outside the container body 100, reducing a space occupied by the power cables in the container body 100, avoiding accumulation and extension of a large number of large-volume power cables in the container body 100, and facilitating the staff's daily inspection, maintenance and upkeep work on the systems, apparatuses and networks in the container body 100.

Further, a cable support structure is disposed between the top of the power distribution cabinet 310 and the cable inlet 802, and the cable support structure includes a cable tray for supporting the power cables and a hoisting structure for hoisting the cable tray to the top of the container body.

As shown in FIGS. 6 and 7, a cable tray 803 is disposed between the top of the power distribution cabinet 310 and the cable inlet 802. The cable tray 803 directly leads from the top of the wall panel 801 to the top of the power distribution cabinet 310, and the power cables, after being introduced from the cable inlet 802, are connected to the power distribution cabinet 310 with the bearing of the cable tray 803. From a perspective inside the container body 100, for example, as viewed from inside the first maintenance passage 500, the cable tray 803 spans the first maintenance passage 500, and the cable tray 803 is located above within the first maintenance passage 500 and between the power distribution cabinet 310 and the wall panel 801. In a daily work process where the staff walk in the first maintenance passage 500, they generally will not touch the cable tray 803, and the existence of the cable tray 803 will not affect the daily work of the staff either.

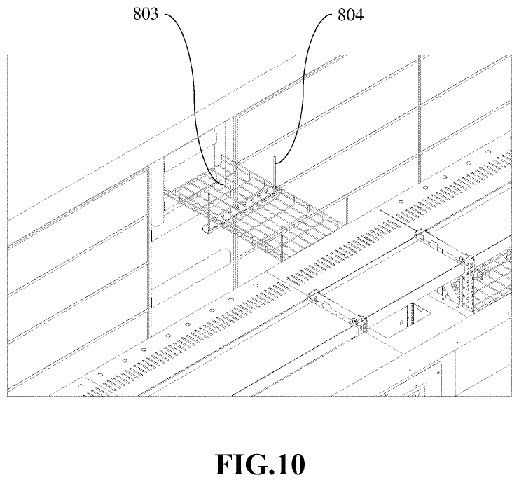

In detail, with reference to FIG. 10, in this embodiment, the cable tray 803 is in a U-shape with two sides bent, and the power cables are connected to the power distribution cabinet 310 from the cable inlet 802 through the cable tray 803, which is safe and reliable. Two sides of the cable tray 803 are provided with baffle rods 804 for preventing the power cables in the cable tray 803 from falling from the sides. Preferably, the baffle rods 804 are disposed in pairs at the middle of the two sides of the cable tray 803, for example. In other embodiments, there may be a plurality of groups of baffle rods 804 as disposed in pairs and disposed at intervals along the two sides of the cable tray 803 to achieve a better anti-falling effect. The baffle rods 804 are made of a higher-strength material, such as a metal material, and may be shaped into a rod or a sheet. Alternatively, tops of the baffle rods 804 that are disposed oppositely may be bent and expanded outward to form introduction ports, which is convenient for introduction of the power cables. Of course, the baffle rods 804 may also serve as a hoisting structure for hoisting the cable tray 803 to the top of the container body 100.

In this embodiment, the cable tray 803 is a mesh structure, which enables timely observation of the load and is light in weight.

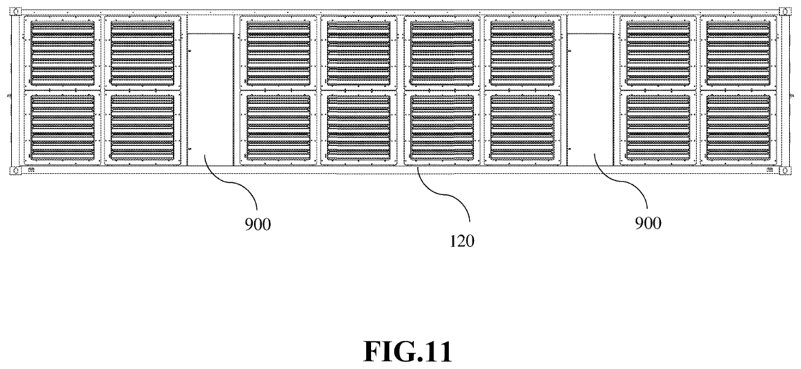

In the server cluster container 1 in some embodiments of the present application, the apparatus row 400 consisting of the power distribution cabinet 310 and the rack 200 is located between the first side heat dissipation long edge 110 and the second side heat dissipation long edge 120. With reference to FIGS. 6 and 11, the second long side edge 120 is provided with a heat dissipation apparatus such as a heat dissipation fan, a position on the second long side edge 120 corresponding to the power distribution cabinet 310 of the apparatus row 400 is provided with a maintenance door 900, the heat dissipation apparatus such as the heat dissipation fan is disposed corresponding to a position of the rack 200 of the apparatus row 400, the heat dissipation apparatus can remove heat emitted by the servers on the rack 200, and the staff can perform professional work such as cleaning, inspection, maintenance, replacement, and upgrading on the power distribution cabinet 310 through the maintenance door 900.

Since the power distribution cabinet 310 is in a high temperature and high humidity working environment, regular maintenance is required to ensure its safe and reliable operation. When maintenance is required, the staff walk to outside of the second long side edge 120 of the container body 100, open the maintenance door 900 facing the power distribution cabinet 310 between the heat dissipation apparatuses, and then may directly enter into the container body 100 to conduct professional work on the power distribution cabinet 310.

It should be noted that maintenance of the power distribution cabinet 310 needs to follow relevant safety standards and operating procedures to avoid safety accidents. During maintenance and repairs, it is necessary to use professional tools and apparatuses, and follow the relevant operating procedures and safety standards.

Based on this, a door lock is disposed on the maintenance door 900 in some embodiments of the present application, which usually supports a plurality of door opening manners, such as password, fingerprint, card swiping, etc. A suitable door opening manner may be selected according to an actual case. The door lock likewise supports a plurality of alarm manners, and alarms are issued for cases where unlocking settings are not met. In simple terms, the door lock may also be locked with a special tool lock, which can only be opened by professional technicians with professional unlocking tools.

As shown in FIG. 2, the container body 100 of the server cluster container 1 in some embodiments of the present application includes a bottom plate 150, the rack 200 extending vertically and being fixed on the bottom plate 150, and the power distribution cabinet 310 being fixed on the bottom plate 150. The apparatus row 400 consisting of the power distribution cabinet 310 and the rack 200 is fixedly connected with the bottom plate 150 of the container body 100, avoiding tipping and shifting during loading, unloading and transportation.

The rack 200 and the power distribution cabinet 310 may be fixed to each other using connectors, making the structure firmer. The server cluster container 1 in some embodiments of the present application provides stable fixation of the rack 200 and the power distribution cabinet 310 inside the container body 100, as well as mutual fixation between the rack 200 and the power distribution cabinet 310, making long-distance transportation more stable and safer.

As shown in FIGS. 2 and 3, the container power distribution bracket arrangement S in some embodiments of the present application includes the racks 200 and the power distribution cabinets 310, the racks 200 and the power distribution cabinets 310 being disposed in a row at intervals, the racks 200 being symmetrically disposed on two sides of the power distribution cabinets 310, and the racks 200 and the power distribution cabinets 310 being fixed to each other. The racks 200 configured on the two sides of the power distribution cabinets 310 have the same specifications to bear the same number of servers. The racks 200 on the two sides of the power distribution cabinets 310 may be separate structures or connected together.

The container power distribution bracket arrangement S in some embodiments of the present application provides a symmetrical configuration of the racks on the two sides of the power distribution cabinet, the same number of servers of the same specifications can be arranged on the racks, so that power lines leading out of the two ends of the power distribution cabinet are evenly distributed and clearly routed, achieving weight balance.

Further, the power distribution cabinet 310 and the racks 200 are correspondingly disposed in a plurality of groups. That is, a plurality of groups of the container power distribution bracket arrangements S in some embodiments of the present application are configured and connected to each other. In the embodiments shown in FIGS. 2 and 3, two groups of container power distribution bracket arrangements S are disposed side by side. In other embodiments, the container power distribution bracket arrangements S may also be disposed in columns or in a matrix, and these are within the scope of protection of the present application.

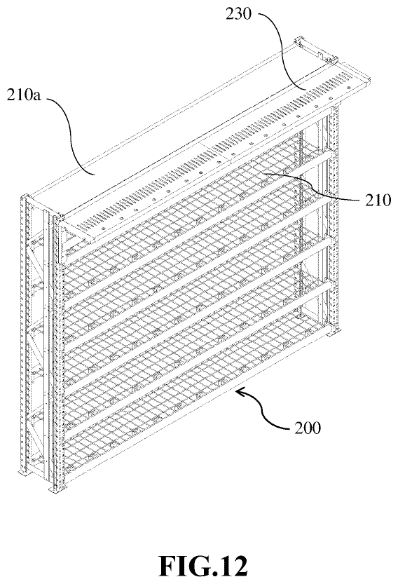

As shown in FIG. 12, the rack 200 includes a partition plate 210 that is in a mesh structure. There are various indicator lights on a server, such as a power indicator light that indicates whether power is on, a network indicator light that indicates whether there is a connection to a network, a status indicator light that indicates a working status, a fault indicator light that indicates whether a fault has occurred, a temperature indicator light that indicates whether temperature is normal, a fan indicator light that indicates whether a fan is running normally, and so on. The indicator lights may provide useful information about the server's status and faults, which helps the staff to diagnose and resolve problems quickly. In order to be aware of a working status of each server, timely attention should be paid to a status of each indicator light.

In some embodiments of the present application, the partition plate 210 of the rack 200 employs a mesh structure, which will not block servers placed thereon.

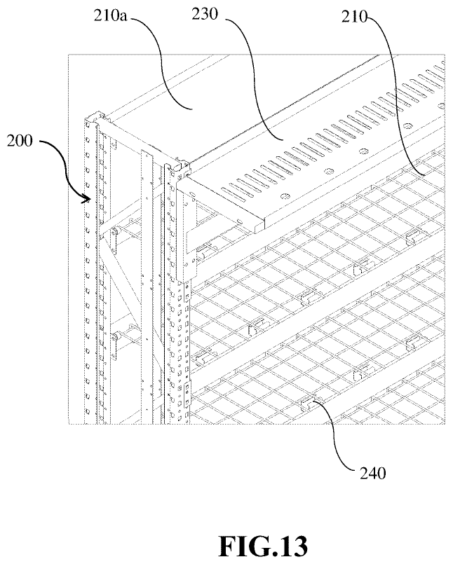

As shown in FIG. 13, the rack 200 includes cable management slots 240 including L-shaped clips that are disposed oppositely for routing and storing communication cables and other cables. The cable management slots 240 are, for example, disposed at intervals along the partition plate 210 to neatly fix the cables in the cable management slots 240. The cable management slots 240 can avoid cables being loose, dropped and entangled, reducing wire damage and thereby improving the apparatus safety and production efficiency, which can also make the container body 100 tidier to provide convenience for the staff's daily maintenance and management.

A containerized server cluster apparatus in some embodiments of the present application is formed by employing the server cluster container 1 to integrate and load a plurality of servers, or in other words, the containerized server cluster apparatus in some embodiments of the present application is formed by employing the server cluster container 1 including a container power distribution bracket arrangement to integrate and load a plurality of servers.

The servers are arranged and disposed on the rack 200 and connected to the power distribution cabinet 310 and other communication modules included in the electronic control system. The containerized server cluster apparatus in some embodiments of the present application may be made to a standard container size and loaded, unloaded and transported together with a standard container, or may be made to a size smaller than that of a standard container and loaded in the standard container for loading, unloading and transportation.

As shown in FIGS. 12 and 13, a distance set between partition layers of the rack 200 corresponds to a height of an upright server. That is, the servers are arranged upright on the partition layers of the rack 200.

The electronic control system includes a plurality of power distributors connected to the power distribution cabinet 310, the power distributors being configured on outer sides of the partition plates 210 of the rack 200 for providing power sources for the servers disposed on the partition plates 210 of the rack 200. In general, the power distributors are configured on the partition plates of the rack 200 that are not at a bottommost layer. That is, no power distributors are configured on a bottommost-layer partition plate of the rack 200, avoiding damage to the power distributors from moisture and stains. Of course, the present application is not limited thereto.

A space at the top of the rack 200 up to the top of the container body 100 is not enough to accommodate an upright server apparatus. In order to improve the computing power of the containerized server cluster apparatus, increasing the number of servers is an effective way to achieve enhanced computing power while ensuring the computing power of a single server.

In the present application, an extension baffle 230 is provided to extend a length of a partition plate 210 at an uppermost layer of the rack 200 along the width direction of the container body 100, so that a server can be laid flat thereon, which increases the number of integrated servers and can improve the computing power of the containerized server cluster apparatus. Of course, in a case where the top space allows, a server located at the topmost layer may be normally arranged upright.

The extension baffle 230 of the rack 200 of the present application is not limited to being disposed on an uppermost-layer partition plate. In some embodiments, the extension baffle 230 extends horizontally out from the partition plates 210 at any one or more positions so as to increase the length of the rack 200 along the width direction. Outer sides of the partition plate 210 and/or the extension baffle 230 are provided with the power distributors.

In some embodiments of the present application, the partition plates 210 include high partition plates higher than or equal to a set height and low partition plates lower than the set height, and the extension baffle 230 is disposed on an outer side of a high partition plate. This set height is, for example, a height of maintenance personnel. That is, the extension baffle 230 is disposed at a position higher than the height of the maintenance personnel, thereby expanding the support space of the rack 200 without affecting the daily work of the maintenance personnel.

There are two power distributors on the partition plate at the topmost layer of the rack 200, one of which is connected with the servers on the partition plate at the topmost layer of the rack 200, and the other of which is connected with servers on a partition plate at a layer directly below the same. The servers on the remaining partition plates are connected with the power distributors on the partition plates at respective upper layers.

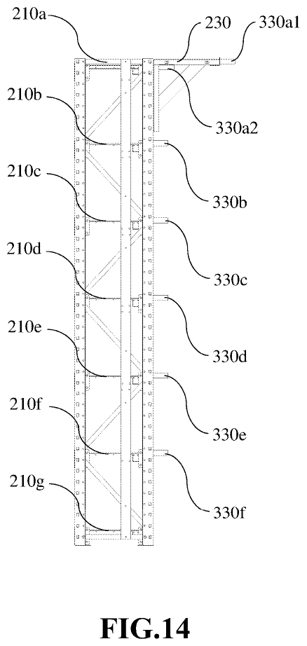

Taking the rack 200 shown in FIG. 14 as an example, the rack 200 has 7 partition plates 210a to 210g from top to bottom, wherein the partition plate 210a is located at a topmost layer, and the partition plate 210g is located at a bottommost layer. Servers are separately arranged and disposed on the partition plates 210a to 210g. An extension baffle 230 is extended on and connected to the topmost-layer partition plate 210a. An outer side of the extension baffle 230 is connected with a power distributor 330a1, and an outer side of the topmost-layer partition plate 210a is connected with a power distributor 330a2. In addition, an outer side of the partition plate 210b is connected with a power distributor 330b, an outer side of the partition plate 210c is connected with a power distributor 330c, an outer side of the partition plate 210d is connected with a power distributor 330d, an outer side of the partition plate 210e is connected with a power distributor 330e, an outer side of the partition plate 210f is connected with a power distributor 330f, and an outer side of the partition plate 210g is not connected with a power distributor.

The servers arranged and disposed on the partition plate 210g are connected with the power distributor 330f at an upper layer, the servers arranged and disposed on the partition plate 210f are connected with the power distributor 330e at an upper layer, the servers arranged and disposed on the partition plate 210e are connected with the power distributor 330d at an upper layer, the servers arranged and disposed on the partition plate 210d are connected with the power distributor 330c at an upper layer, the servers arranged and disposed on the partition plate 210c are connected with the power distributor 330b at an upper layer, the servers arranged and disposed on the partition plate 210b are connected with the power distributor 330a2 at an upper layer, and the servers arranged and disposed on the partition plate 210a are connected with the power distributor 330a1.

That is to say, the partition plates below the topmost-layer partition plate form “up-down” connection relationships in which a power distributor on an upper-layer partition plate is connected to servers on a lower-layer partition plate. This is not only convenient to operate, but also can reduce damage to the power distributors caused by moisture and stains in the container body 100.

In related technologies, each power distributor is provided with a switch to control power on or off. In some embodiments, the power distribution cabinet 310 is provided with a switch module for controlling each power distributor, and the switch module achieves independent control of each power distributor. For example, the switch module controls the power on or off of each power distributor. When a certain power distributor needs to be maintained or servers connected to a certain power distributor need to be powered off for maintenance, it is only necessary to use the switch module to power off the power of this certain power distributor alone, which facilitates maintenance and improves safety. Furthermore, since the switch modules are centrally provided in the distribution cabinet, the centralized control of all the power distributors can be achieved, which is convenient for operation. For example, when a plurality of power distributors need to be turned off or on, there is no need to separately walk near the respective power distributors for operation.

Referring to FIGS. 12 and 13, in order to enhance the overall strength of the rack 200, in an embodiment of the present application, the topmost-layer partition plate 210a and the extension baffle 230 are in the shape of a plate body, and the staff cannot be timely aware of a working status of the servers located on the topmost-layer partition plate 210a during maintenance. The containerized server cluster apparatus in some embodiments of the present application further includes a top-layer apparatus status feedback means for feeding back a top-layer apparatus status. The top-layer apparatus status feedback means is implemented in various ways such as software monitoring, hardware monitoring, remote monitoring and log monitoring.

In an embodiment of the present application, the top-layer apparatus status feedback means employs a reflective mirror observation means connected to the servers disposed on the corresponding topmost-layer partition plate 210a in the container body 100 The number of the reflective mirror observation means is at least one, and each reflective mirror observation means corresponds to at least one server. For example, each reflective mirror observation means corresponds to 1, 2, or more servers, and the present application makes no limitation in this regard.

The reflective mirror observation means includes a plurality of feedback areas, each corresponding to at least one server disposed on the topmost-layer partition plate 210a for feeding back a working status of the at least one server. There may be one or more reflective mirror observation means, which feeds back a working status of each server in real time, facilitating timely processing by the staff and ensuring the working efficiency of the apparatus.

In other embodiments, the topmost-layer partition plate 210a and the extension baffle 230 may likewise be made into a mesh shape to facilitate monitoring of their status by the staff. In this case, the provision of the top-layer apparatus status feedback means may be canceled.

In some embodiments, the server cluster container 1 includes a top partition plate and a top corrugated plate that are disposed oppositely, with a top wiring pipeline located between the top partition plate and the top corrugated plate. The top partition plate provides concealment and protection for the top wiring pipeline. In some embodiments, an upper side of the top partition plate is further provided with a heat-insulating layer for isolating external heat from entering an area below the top partition plate. The heat-insulating layer employs heat-insulating materials. Further, a foaming material, such as a polyurethane foaming material, is filled between the heat-insulating layer and the top corrugated plate to further enhance the heat insulation effect.

The containerized server cluster apparatus in some embodiments of the present application further includes an intelligent monitoring system connected to the servers and the electronic control system. The intelligent monitoring system can improve the reliability, stability, and safety of the apparatus, reduce the maintenance costs and improve the working efficiency, and can also provide data support to help the management and optimization of the apparatus.

The intelligent monitoring system further includes an access control module, a lighting sensor module, an anti-theft monitoring module, a fire prevention module, a flood alarm module, and so on.

By way of example, the intelligent monitoring system of the containerized server cluster apparatus may be configured in several steps as below:
determining monitoring indicators: first, it is necessary to determine indicators that need to be monitored, such as structural operating status, temperature, access control, lighting, monitoring, fire protection and other information. These indicators may be determined specifically according to the usage environment.
selecting sensors and monitoring apparatuses: appropriate sensors and monitoring apparatuses are used according to the indicators that need to be monitored. For example, a temperature sensor, an access controller, a lighting controller, a monitoring camera and other apparatuses may be selected to collect information such as temperature, access control status, light intensity, image, etc., and convert the information into useful information that can be used to monitor apparatus status, predict apparatus failures, optimize production processes, etc.
connecting the apparatuses and sensors: the sensors and monitoring apparatuses are connected to the containerized server cluster apparatus, for example, through a network connection or a physical connection.
installing monitoring components: the monitoring components can monitor the status, performance, logs and other information of the apparatus, and provide alarm and notification functions.
configuring the monitoring system: the monitoring system is configured as needed, for example, by setting the monitoring indicators, alarm thresholds, notification modes, etc.

In testing and use processes, the system's functions and performance can be continuously optimized and adjusted to ensure the normal operation and accuracy of the monitoring system and meet use requirements. A human-machine interface may be employed to display on-site data and information to operators in an intuitive manner through display screens, keyboards, mice and other devices, making it convenient for them to monitor and control. Also, a cloud platform may be used to implement functions such as remote monitoring, remote maintenance, and data analysis to improve the production efficiency and management level.

The intelligent monitoring system in some embodiments of the present application further includes system operation and maintenance and infrastructure operation and maintenance monitoring, and can configure and switch control the apparatus through a remote operating platform.

In an embodiment of the server cluster container of the present application, a server cluster container 2 includes a container body 100, a rack 200 and an electronic control system, the rack 200 and the electronic control system being respectively disposed and integrated in the container body 100, wherein the rack 200 is used for bearing a plurality of servers, and the electronic control system connects the plurality of servers borne on the rack 200 to provide services such as power distribution and communication for the servers. The rack 200 and the power distribution cabinet 310 are disposed in a row along a length direction of the container body 100 to form an apparatus row 400, making full use of a space inside the container body 100. In the present application, the racks 200 are configured to be symmetrically disposed on two sides of the power distribution cabinet 310. The container body 100 includes a first side heat dissipation long edge 110, a second side heat dissipation long edge 120, a first side short edge 130, and a second side short edge 140, wherein the first side heat dissipation long edge 110 and the second side heat dissipation long edge 120 are symmetrically disposed along the length direction of the container body 100, and the first side short edge 130 and the second side short edge 140 are symmetrically disposed along the width direction of the container body 100. The server cluster container 2 is a hexahedral shape formed by extending the first side heat dissipation long edge 110, the second side heat dissipation long edge 120, the first side short edge 130 and the second side short edge 140 to a height, a size of which may be the same as a current mainstream standard container size, such as 20-foot, 40-foot, etc. During loading, unloading and transportation, the same loading, unloading and transportation forms as those of standard containers may be employed. For example, the same loading and unloading equipment as that for standard containers, such as hoisting and forklifts, as well as the same transportation equipment such as land transportation vehicles and sea transportation ships may be used, which greatly reduces transportation costs. Of course, the server cluster container 2 may also be smaller than a standard container, which, when transported, is loaded in the standard container to avoid damage such as collision and displacement that may occur in transportation, loading and unloading processes. Further, one standard container may be loaded with one or more of the server cluster containers 2 in some embodiments of the present application.

The apparatus row 400 formed by disposing the racks 200 and the power distribution cabinets 310 in a row is disposed along a direction in which the first side heat dissipation long edge 110 and the second side heat dissipation long edge 120 extend, and two sides of the apparatus row 400 respectively abut against the first side short edge 130 and the second side short edge 140.

A first maintenance passage 500 is provided between the first side heat dissipation long edge 110 and the apparatus row 400, and doors 600 are provided at positions of the first side short edge 130 and the second side short edge 140 corresponding to the first maintenance passage 500.

The apparatus row 400 is disposed in parallel between the first side heat dissipation long edge 110 and the second side heat dissipation long edge 120, and the first maintenance passage 500 between the first side heat dissipation long edge 110 and the apparatus row 400 is used for the staff to conduct regular inspection, maintenance and upkeep for systems, apparatuses, networks, and the like to ensure that they can normally operate, prevent failures and accidents, and improve the reliability and stability of the systems.

The first maintenance passage 500 in some embodiments of the present application is spacious and smooth, and at least one side of the first side short edge 130 and the second side short edge 140 corresponding to the first maintenance passage 500 is provided with a door 600. For example, doors 600 are respectively disposed on the first side short edge 130 and the second side short edge 140, and the staff may enter the first maintenance passage 500 from one of the doors 600, to inspect, maintain and service the systems, apparatuses and networks in the container body 100, and then walk out from the other door 600, which is convenient and quick and can effectively improve the working efficiency.

Positions of the first side short edge 130 and the second side short edge 140 corresponding to the rack 200 and between the rack 200 and the second side heat dissipation long edge 120 are provided with closed walls 700. That is to say, the doors 600 disposed on the first side short edge 130 and the second side short edge 140 are half-open doors, and only the positions thereof corresponding to the first maintenance passage 500 are openable/closeable doors, while where the first side short edge 130 and the second side short edge 140 do not correspond to the first maintenance passage 500, there are closed walls sealed to top, which simplifies unnecessary design, and reduces safety hazards and the costs of maintenance and apparatus manufacturing.

The first side heat dissipation long edge 110 is provided with a dustproof mesh and/or shutters, and the second side heat dissipation long edge 120 is provided with a cooling structure. In addition, a water curtain structure may be further mounted on an outer side of the first side heat dissipation long edge 110 to further improve the heat dissipation effect.

Part of the first side heat dissipation long edge 110 corresponding to the power distribution cabinet 310 of the apparatus row 400 is further provided with a wall panel 801, and the shutters (and/or dustproof mesh) are disposed corresponding to the position of the rack 200, ensuring that external wind enters the container body 100 through the shutters (and/or dustproof mesh), while avoiding moisture or sunlight from damaging the power distribution cabinet 310. As shown in FIG. 9, the wall panel 801 is disposed between adjacent shutters (and/or dustproof meshes).

The wall panel 801 is made of, for example, a steel plate. Part of the wall panel 801 may be added with transverse and longitudinal reinforcing ribs to improve the overall strength of the container body 100, enhance the resistance of the container body 100 to deformation and extrusion, and reduce the possibility of damage during loading, unloading and transportation.

Further, a top of the wall panel 801 has a cable inlet 802 disposed corresponding to a top end of the power distribution cabinet 310.

A server consumes a lot of electricity, and the cross-sectional area of the server power cables needs to be large enough to meet the high power requirements of the server. When the power distribution cabinet 310 needs to power a large number of servers, both the number and volume of power cables connected with the power distribution cabinet 310 are relatively large.

In some embodiments of the present application, by disposing at a top end of the wall panel 801 the cable inlet 802 that directly corresponds to the top of the power distribution cabinet 310, the power cables are introduced through the cable inlet 802 and connected to the power distribution cabinet 310, resulting in a direct path, shortening a length of the power cables inside and outside the container body 100, reducing a space occupied by the power cables in the container body 100, avoiding accumulation and extension of a large number of large-volume power cables in the container body 100, and facilitating the staff's daily inspection, maintenance and upkeep work on the systems, apparatuses and networks in the container body 100.

Further, a cable tray 803 is disposed between the top of the power distribution cabinet 310 and the cable inlet 802. The cable tray 803 directly leads from the top of the wall panel 801 to the top of the power distribution cabinet 310, and the power cables, after being introduced from the cable inlet 802, are connected to the power distribution cabinet 310 with the bearing of the cable tray 803. From a perspective inside the container body 100, for example, as viewed from inside the first maintenance passage 500, the cable tray 803 spans the first maintenance passage 500, and the cable tray 803 is located above within the first maintenance passage 500 and between the power distribution cabinet 310 and the wall panel 801. In a daily work process where the staff walk in the first maintenance passage 500, they generally will not touch the cable tray 803, and the existence of the cable tray 803 will not affect the daily work of the staff either.

The cable tray 803 is, for example, in a U-shape with two sides bent, and the power cables are connected to the power distribution cabinet 310 from the cable inlet 802 through the cable tray 803, which is safe and reliable. Two sides of the cable tray 803 are provided with baffle rods 804 for preventing the power cables in the cable tray 803 from falling from the sides. Preferably, the baffle rods 804 are disposed in pairs at the middle of the two sides of the cable tray 803, for example. In other embodiments, there may be a plurality of groups of baffle rods 804 as disposed in pairs and disposed at intervals along the two sides of the cable tray 803 to achieve a better anti-falling effect. The baffle rods 804 are made of a higher-strength material, such as a metal material, and may be shaped into a rod or a sheet. Alternatively, tops of the baffle rods 804 that are disposed oppositely may be bent and expanded outward to form introduction ports, which is convenient for introduction of the power cables. The baffle rods 804 may also serve as a hoisting structure for hoisting the cable tray 803 to the top of the container body 100. The cable tray 803 is a mesh structure, which enables timely observation of the load and is light in weight.

Of course, the present application may have many other embodiments. Without departing from the spirit and essence of the present application, those skilled in the art may make various corresponding changes and modifications according to the present application, but these corresponding changes and modifications should all fall within the scope of protection of the attached claims of the present application.

### INDUSTRIAL APPLICABILITY

A server cluster container of the present application includes a container body, and a rack and an electronic control system which are respectively disposed in the container body, the electronic control system including a power distribution cabinet connected with servers borne on the rack; and the container body including a first side heat dissipation long edge that extends along a length direction and is provided with a water curtain structure. A containerized server cluster apparatus of the present application includes a plurality of servers and the above server cluster container, the servers being arranged and disposed on the rack and connected to the electronic control system. The present application improves the working efficiency of a server cluster through a reasonable layout in the container, and dissipates heat for the servers in the container body to ensure high-efficiency operation of the system.

1. A server cluster container, comprising a container body, and a rack and an electronic control system which are respectively disposed in the container body, the electronic control system comprising a power distribution cabinet connected with servers borne on the rack.

2. The server cluster container according to claim 1, wherein the rack and the power distribution cabinet are disposed in a row along a length direction of the container body to form an apparatus row.

3. The server cluster container according to claim 1, wherein racks are configured on two sides of the power distribution cabinet.

4. The server cluster container according to claim 1, wherein the container body comprises a first side heat dissipation long edge extending along the length direction, the first side heat dissipation long edge being provided with a dustproof mesh and/or a shutter structure and/or a water curtain structure.

5. The server cluster container according to claim 1, wherein the container body comprises a second side heat dissipation long edge extending along the length direction, a position on the second side heat dissipation long edge corresponding to the power distribution cabinet being provided with a maintenance door;
wherein the second side heat dissipation long edge is provided with a cooling structure.

6. (canceled)

7. The server cluster container according to claim 2, wherein a first maintenance passage is present between a first side heat dissipation long edge and the apparatus row of the container body;
wherein the container body comprises a first side short edge and a second side short edge which extend symmetrically along a width direction, a position of the first side short edge and/or the second side short edge corresponding to the first maintenance passage being provided with a door;
wherein a floor in the container body corresponding to the first maintenance passage is an insulating panel.

8-9. (canceled)

10. The server cluster container according to claim 1, wherein positions of a first side short edge and/or a second side short edge of the container body corresponding to the rack and positions between the rack and a second side heat dissipation long edge of the container body are provided with closed walls.

11. The server cluster container according to claim 2, wherein a second maintenance passage is present between a second side heat dissipation long edge and the apparatus row of the container body;
wherein a width of the second maintenance passage along the width direction of the container body is greater than a thickness of a cooling structure;
wherein a floor in the container body corresponding to the second maintenance passage is a steel plate.

12-13. (canceled)

14. The server cluster container according to claim 1, wherein a position on a first side heat dissipation long edge of the container body corresponding to the power distribution cabinet is provided with a wall panel, a top of the wall panel having a cable inlet corresponding to a top end of the power distribution cabinet;
wherein a cable support structure is disposed between the top of the power distribution cabinet and the cable inlet;
wherein the cable support structure comprises a cable tray for supporting power cables and a hoisting structure for hoisting the cable tray to the top of the container body.

15-16. (canceled)

17. The server cluster container according to claim 1, wherein the container body comprises a bottom plate, the rack extending vertically and being fixed on the bottom plate, and the power distribution cabinet being fixed on the bottom plate;
wherein the rack and the power distribution cabinet are fixedly disposed.

18. (canceled)

19. The server cluster container according to claim 1, wherein the rack comprises a plurality of partition plates that are in a mesh structure.

20. The server cluster container according to claim 1, wherein the rack comprises a cable management slot comprising L-shaped clips that are disposed oppositely.

21. The server cluster container according to claim 19, wherein the electronic control system comprises a plurality of power distributors connected to the power distribution cabinet, the power distributors being configured on outer sides of the partition plates;
wherein the power distributors are configured on the partition plates that are not at a bottommost layer.

22. (canceled)

23. The server cluster container according to claim 21, wherein the rack further comprises an extension baffle extending horizontally out from the partition plate;
wherein outer sides of the partition plate and/or the extension baffle is provided with the power distributors;
wherein the partition plates comprise high partition plates higher than or equal to a set height and low partition plates lower than the set height, and the extension baffle is disposed on an outer side of each of the high partition plates.

24-25. (canceled)

26. The server cluster container according to claim 23, wherein the extension baffle is disposed on an outer side of a topmost-layer one of the partition plates.

27. The server cluster container according to claim 26, further comprising a top-layer apparatus status feedback means;
wherein the top-layer apparatus status feedback means comprises a reflective mirror observation means;
wherein the reflective mirror observation means comprises a plurality of feedback areas, each corresponding to at least one of the servers disposed on the topmost-layer partition plate and/or the extension baffle.

28-29. (canceled)

30. The server cluster container according to claim 1, further comprising an intelligent monitoring system connected to the electronic control system;
wherein the intelligent monitoring system further comprises one of an access control module, a lighting sensor module, an anti-theft monitoring module and a fire prevention module.

31. (canceled)

32. The server cluster container according to claim 1, wherein a side of the rack along the length direction of the container body is provided with an isolation plate;
wherein the isolation plate is disposed close to air outlets of the servers borne on the rack.

33. (canceled)

34. The server cluster container according to claim 32, wherein the isolation plate is provided with vents corresponding to the air outlets of the servers borne on the rack.

35. A containerized server cluster apparatus, comprising a plurality of servers, wherein the containerized server cluster apparatus further comprises the server cluster container according to claim 1, the servers being arranged and disposed on the rack and connected to the electronic control system.
